(19) United States
(12) Patent Application Publication
(10) Pub. No.: US 2022/0180927 A1
(43) Pub. Date: Jun. 9, 2022

(54) STORAGE DEVICE AND STORAGE CONTROL DEVICE

(71) Applicant: SONY SEMICONDUCTOR SOLUTIONS CORPORATION, Kanagawa (JP)

(72) Inventor: Haruhiko TERADA, Kanagawa (JP)

(73) Assignee: SONY SEMICONDUCTOR SOLUTIONS CORPORATION, Kanagawa (JP)

(21) Appl. No.: 17/601,146

(22) PCT Filed: Feb. 10, 2020
(86) PCT No.: PCT/JP2020/005065

§ 371 Date: Oct. 4, 2021

(30) Foreign Application Priority Data
Apr. 16, 2019 (JP) 2019-078010

(51) Int. Cl. G11C 13/00

(52) U.S. Cl. CPC G11C 13/0038; G11C 13/0028; G11C 13/0026

(57) ABSTRACT

Parallelism of memory access is improved without sacrificing operation margin. A storage unit includes a plurality of first lines extending in a first direction, a plurality of second lines extending in a second direction, and a plurality of memory cells each being inserted at a position at which any one of the plurality of first lines intersects any one of the plurality of second lines. A first driving unit supplies a first voltage having either a positive or a negative polarity to each of the plurality of first lines. A second driving unit supplies a second voltage having a polarity different from the first voltage to one of the plurality of second lines intersecting the plurality of first lines and supplies either a zero potential or a voltage having the same polarity as the first voltage to the remaining second lines intersecting the plurality of first lines.

### TECHNICAL FIELD

The present technology relates to a storage device. Specifically, the present technology relates to a storage device storing data and a storage control device thereof.

### BACKGROUND ART

Conventionally, a nonvolatile memory device using a resistive random-access memory that performs data access at a higher speed than a flash memory and the like has attracted attention. For example, a technology for simultaneously writing data on a plurality of memory cells in a cross point type nonvolatile semiconductor storage device is proposed (refer to PTL 1, for example).

### CITATION LIST

### Patent Literature

[PTL 1]
JP 2006-323924 A

### SUMMARY

### Technical Problem

In the aforementioned conventional technology, simultaneous access to a plurality of memory cells has been attempted. However, in this conventional technology, current paths of the plurality of memory cells may overlap on a bit line or a word line and thus operational margins may deteriorate.

The present technology has been devised in such circumstances and an object of the present technology is to improve parallelism of memory access without sacrificing an operation margin.

### Solution to Problem

A first aspect of the present technology devised to solve the above-described problems is a storage device and a storage control device including: a storage unit including a plurality of first lines extending in a first direction, a plurality of second lines extending in a second direction different from the first direction, and a plurality of memory cells each being inserted at a position at which any one of the plurality of first lines intersects any of the plurality of second lines; a plurality of first driving units configured to supply a first voltage having either a positive or a negative polarity to the plurality of first lines; and a plurality of second driving units configured to supply a second voltage having a polarity different from the first voltage to one of the plurality of second lines intersecting the plurality of first lines and to supply either a zero potential or a voltage having the same polarity as the first voltage to the remaining second lines intersecting the plurality of first lines. Accordingly, the effect of selecting a memory cell at a position at which a first line to which the first voltage is supplied intersects a second line to which the second voltage is supplied and securing an independent current path with respect to the selected memory cell by supplying a zero potential to second lines of the other memory cells is obtained.

Furthermore, in the first aspect, the plurality of first driving units may be provided for the plurality of memory cells sharing one of the plurality of first lines, and the plurality of second driving units may be provided for the plurality of memory cells sharing one of the plurality of second lines. Accordingly, the effect of driving a line for each of the plurality of memory cells is obtained.

Furthermore, in the first aspect, when the structure is divided into a plurality of unit structures including a predetermined number of the plurality of first driving units and a predetermined number of the plurality of second driving units, voltage supply patterns for the plurality of first and second lines of neighboring unit structures among the plurality of unit structures may be different from each other. Accordingly, the effect of supplying voltages consistently in the entire structure obtained by combining the unit structures is obtained.

Furthermore, in the first aspect, the plurality of first and second driving units at a boundary between neighboring unit structures among the plurality of unit structures may be shared by the neighboring unit structures. Accordingly, the effect of supplying voltages consistently even on lines on unit structures is obtained.

Furthermore, in the first aspect, each of the plurality of memory cells may include a storage element having either a first resistance state or a second resistance state, and the storage element may be set to either the first resistance state or the second resistance state in response to a direction of current flowing when voltages with different polarities are applied to the first and second lines. Accordingly, the effect of securing an independent current path with respect to a memory cell using a resistive random-access memory is obtained.

Furthermore, in the first aspect, the plurality of memory cells may include first and second storage elements sharing one of the plurality of first lines. Accordingly, the effect of securing an independent current path with respect to a selected memory cell in a structure in which memory cells are stacked in two levels is obtained. Furthermore, in this case, the plurality of second driving units may supply a voltage with a zero potential to the second line of one of the first and second storage elements and supply a voltage having either a positive or a negative polarity to the second line of the other. Accordingly, the effect of selecting, from two-level memory cells, only one-level memory cell is obtained.

Furthermore, in the first aspect, the storage device and the storage control device may further include a plurality of sense amplifiers connected to the plurality of second lines to correspond to the plurality of second driving units. Accordingly, the effect of connecting sense amplifiers to the second lines having a smaller parasitic capacitance is obtained.

Furthermore, in the first aspect, the storage device and the storage control device may further include a control circuit configured to supply a control signal indicating polarities of voltages to be applied to the plurality of first and second lines to the plurality of first and second driving units. Accordingly, the effect of causing the first and second driving units to supply voltages according to an instruction from the control circuit and securing an independent current path with respect to a selected memory cell is obtained.

### BRIEF DESCRIPTION OF DRAWINGS

FIG. 1 is a diagram illustrating an example of an overall configuration of a storage device 300 in an embodiment of the present technology.

FIG. 2 is a diagram illustrating an example of a configuration of a resistive random-access memory cell 10 in an embodiment of the present technology.

FIG. 3 is a diagram schematically showing an example of a distribution of resistance values of the resistive random-access memory cell 10 in an embodiment of the present technology.

FIG. 4 is a diagram illustrating an example of a configuration of sub-tiles in a memory bank 310 in an embodiment of the present technology.

FIG. 5 is a diagram illustrating an example of a configuration of tiles in the memory bank 310 in an embodiment of the present technology.

FIG. 6 is a diagram illustrating an example of notation of an upper memory cell 111 and a lower memory cell 112 in an embodiment of the present technology.

FIG. 7 is a diagram illustrating an example of notation of a tile 320 in an embodiment of the present technology.

FIG. 8 is a diagram illustrating an example of voltages applied to the upper memory cell 111 and the lower memory cell 112 in an embodiment of the present technology.

FIG. 9 is a diagram illustrating an example of a circuit layout of the memory bank 310 in an embodiment of the present technology.

FIG. 10 is a diagram illustrating an example of a circuit layout of a memory die of the storage device 300 in an embodiment of the present technology.

FIG. 11 is a diagram illustrating a first pattern example (pattern A) of applied voltages at the time of a set operation or a sense operation in an embodiment of the present technology.

FIG. 12 is a diagram illustrating a second pattern example (pattern B) of the applied voltages at the time of a set operation or a sense operation in an embodiment of the present technology.

FIG. 13 is a diagram illustrating a third pattern example (pattern C) of the applied voltages at the time of the set operation or the sense operation in an embodiment of the present technology.

FIG. 14 is a diagram illustrating a fourth pattern example (pattern D) of the applied voltages at the time of the set operation or the sense operation in an embodiment of the present technology.

FIG. 15 is a diagram illustrating a fifth pattern example (pattern E) of the applied voltages at the time of the set operation or the sense operation in an embodiment of the present technology.

FIG. 16 is a diagram illustrating a sixth pattern example (pattern F) of the applied voltages at the time of the set operation or the sense operation in an embodiment of the present technology.

FIG. 17 is a diagram illustrating a seventh pattern example (pattern G) of the applied voltages at the time of the set operation or the sense operation in an embodiment of the present technology.

FIG. 18 is a diagram illustrating an eighth pattern example (pattern H) of the applied voltages at the time of the set operation or the sense operation in an embodiment of the present technology.

FIG. 19 is a diagram illustrating a first pattern example (pattern A) of applied voltages at the time of a reset operation in an embodiment of the present technology.

FIG. 20 is a diagram illustrating a second pattern example (pattern B) of the applied voltages at the time of the reset operation in an embodiment of the present technology.

FIG. 21 is a diagram illustrating a third example (pattern C) of the applied voltages at the time of the reset operation in an embodiment of the present technology.

FIG. 22 is a diagram illustrating a fourth pattern example (pattern D) of the applied voltages at the time of the reset operation in an embodiment of the present technology.

FIG. 23 is a diagram illustrating a fifth pattern example (pattern E) of the applied voltages at the time of the reset operation in an embodiment of the present technology.

FIG. 24 is a diagram illustrating a sixth pattern example (pattern F) of the applied voltages at the time of the reset operation in an embodiment of the present technology.

FIG. 25 is a diagram illustrating a seventh pattern example (pattern G) of the applied voltages at the time of the reset operation in an embodiment of the present technology.

FIG. 26 is a diagram illustrating an eighth pattern example (pattern H) of the applied voltages at the time of the reset operation in an embodiment of the present technology.

FIG. 27 is a diagram illustrating an example of arrangement of patterns of applied voltages in an embodiment of the present technology.

FIG. 28 is a diagram illustrating an example of combinations of arrangements of patterns of applied voltages in an embodiment of the present technology.

FIG. 29 is a diagram illustrating an example of a configuration of a bank control circuit 390 in an embodiment of the present technology.

FIG. 30 is a diagram illustrating an example of arrangement of address lines for supplying address signals from the bank control circuit 390 in an embodiment of the present technology.

FIG. 31 is a diagram illustrating an example of names of address signals supplied from the bank control circuit 390 in an embodiment of the present technology.

FIG. 32 is a diagram illustrating an example of details of the address signals supplied from the bank control circuit 390 in an embodiment of the present technology.

FIG. 33 is a diagram illustrating an example of arrangement of a sense amplifier 290 in an embodiment of the present technology.

### DESCRIPTION OF EMBODIMENTS

Hereinafter, forms for carrying out the present technology (hereinafter referred to as embodiments) will be described. The description will be made in the following order.

### 1. Embodiment (Example of Application to Two-Level Cross Point Memory)

2. Modified Examples (with Respect to Configurations of Three Levels or More)

### 1. Embodiment

### [Overall Configuration of Storage Device]

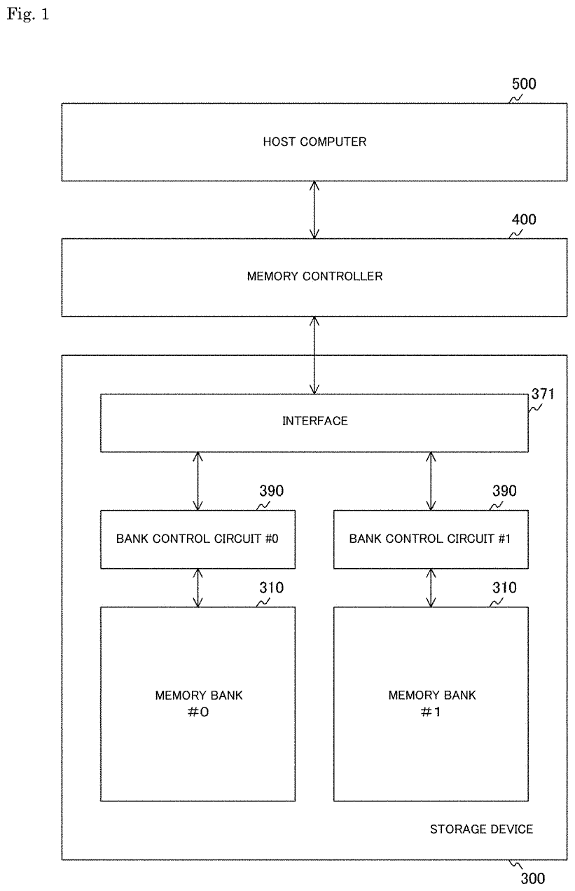

FIG. 1 is a diagram illustrating an example of an overall configuration of a storage device 300 in an embodiment of the present technology.

The storage device 300 has, for example, two bank components and includes memory banks 310 and bank control circuits 390. Each memory bank 310 includes a memory array in which resistive random-access memory cells are arranged in a matrix form. Each bank control circuit 390 is provided to correspond to one memory bank 310 and controls access to the memory bank 310 corresponding thereto.

In addition, the storage device 300 includes an interface 371 between the storage device 300 and a memory controller 400. A host computer 500 is connected to the memory controller 400 and an access command is issued from the host computer 500 to the storage device 300 via the memory controller 400. The interface 371 communicates with the memory controller 400 and mediates the bank control circuit 390 of each bank.

### [Resistive Random-Access Memory Cell]

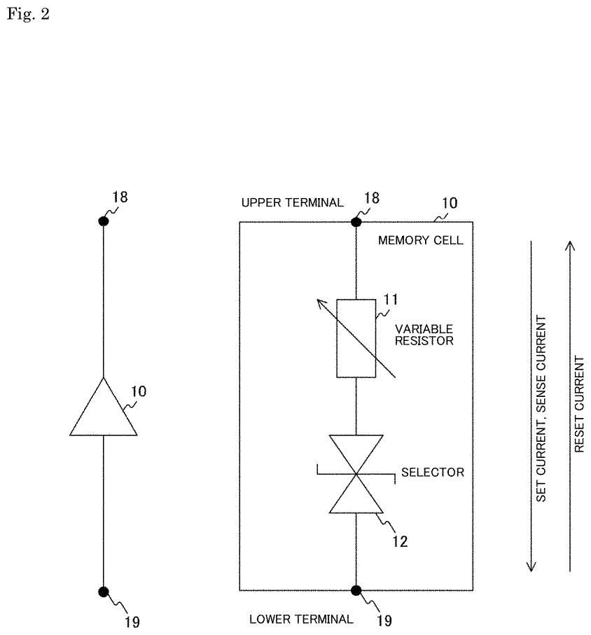

FIG. 2 is a diagram illustrating an example of a configuration of a resistive random-access memory cell 10 in an embodiment of the present technology.

The memory cell 10 has a serial structure of a variable resistor 11 and a selector 12. The variable resistor 11 is an element that reversibly changes resistance states in response to a potential difference of a voltage applied to both ends thereof. The selector 12 is an element having bidirectional diode characteristics, switches to a conductive (on) state when the absolute value of a potential difference of a voltage applied to both poles thereof is greater than a predetermined potential difference and switches to a nonconductive (off) state when the absolute value is less than the predetermined potential difference.

The memory cell 10 includes an upper terminal 18 connected to the variable resistor 11 and a lower terminal 19 connected to the selector 12. When the selector 12 is in a conductive state, a set operation or a sense operation is performed in response to a voltage across both ends of the variable resistor 11 if current flows from the upper terminal 18 to the lower terminal 19. On the other hand, if current flows from the lower terminal 19 to the upper terminal 18, a reset operation is performed in response to the voltage across both ends of the variable resistor 11.

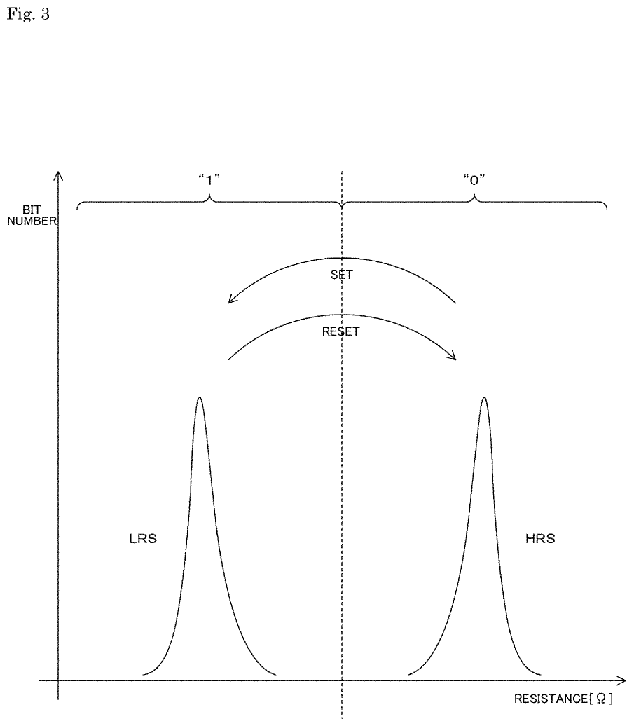

FIG. 3 is a diagram schematically showing an example of a distribution of resistance values of the resistive random-access memory cell 10 in an embodiment of the present technology. In the figure, the horizontal axis represents resistance and the vertical axis represents a distribution of bit numbers.

The variable resistor 11 may have any one of a high resistance state (HRS) and a low resistance state (LRS). The high resistance state HRS is associated with data “0” and the low resistance state LRS is associated with data “1” in this example. That is, the variable resistor 11 serves as a storage element storing 1-bit data.

An operation of changing the resistance state of the variable resistor 11 from the high resistance state HRS to the low resistance state LRS is referred to as a set operation and an operation of changing the resistance state from the low resistance state LRS to the high resistance state HRS is referred to as a reset operation. In addition, an operation of reading the resistance state of the variable resistor 11 is referred to as a sense operation.

### [Sub-tile]

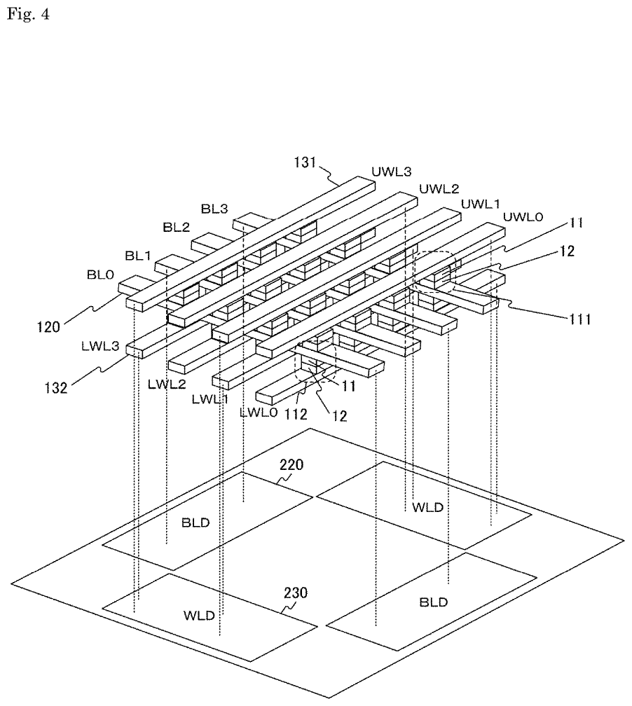

FIG. 4 is a diagram illustrating an example of a configuration of a sub-tile in the memory bank 310 in an embodiment of the present technology.

In this embodiment, a two-level cross point memory including a two-level memory array in which a memory array composed of the aforementioned memory cell 10 is stacked in two levels is assumed. In an upper memory cell 111, an upper word line (UWL) 131 is connected to the upper terminal 18 of the variable resistor 11 and a bit line (BL) 120 is connected to the lower terminal 19 of the selector 12. On the other hand, in a lower memory cell 112, the bit line 120 is connected to the upper terminal 18 of the variable resistor 11 and a lower word line (LWL) 132 is connected to the lower terminal 19 of the selector 12.

In this manner, both the upper memory cell 111 and the lower memory cell 112 include the variable resistor 11 on the upper sides thereof and include the selector 12 on the lower sides thereof. Accordingly, it is possible to facilitate manufacture and align characteristics of the two levels.

Further, in this structure, the upper memory cell 111 and the lower memory cell 112 share the bit line 120. Accordingly, it is possible to facilitate manufacture and reduce the number of peripheral circuit components.

In this example, four bit lines 120 extend in a first direction and four upper word lines B1 and lower word lines 132 extend in a second direction. For example, it is assumed that the first direction in which the bit lines 120 extend is the vertical direction and the second direction in which the upper word lines B1 and the lower word lines 132 extend is the horizontal direction in the plane of the memory array.

A total of 16 upper memory cells 111 are inserted at positions at which the four upper word lines B1 intersect the four bit lines 120. In addition, a total of 16 lower memory cells 112 are inserted at positions at which the four bit lines 120 intersect the four lower word lines 132. That is, accordingly, a cross point memory composed of the two-level memory array is configured.

A bit line decoder (BLD) 220 and a word line decoder (WLD) 230 are disposed on a substrate surface under the memory array. The bit line decoder 220 applies a voltage to the bit lines 120 according to an instruction from the bank control circuit 390. The word line decoder 230 applies a voltage to the upper word lines 131 and the lower word lines 132 according to an instruction from the bank control circuit 390. In this example, the bit lines 120 are connected to the bit line decoder 220 at two sides facing each other among the four sides of the memory array and the upper word lines B1 and the lower word lines 132 are connected to the word line decoder 230 at the other two sides.

The structure composed of the four bit lines 120, the four upper word lines B1, the four lower word lines 132, the 16 upper memory cells 111, the 16 lower memory cells 112, the bit line decoder 220, and the word line decoder 230 is referred to as a sub-tile.

### [Tile]

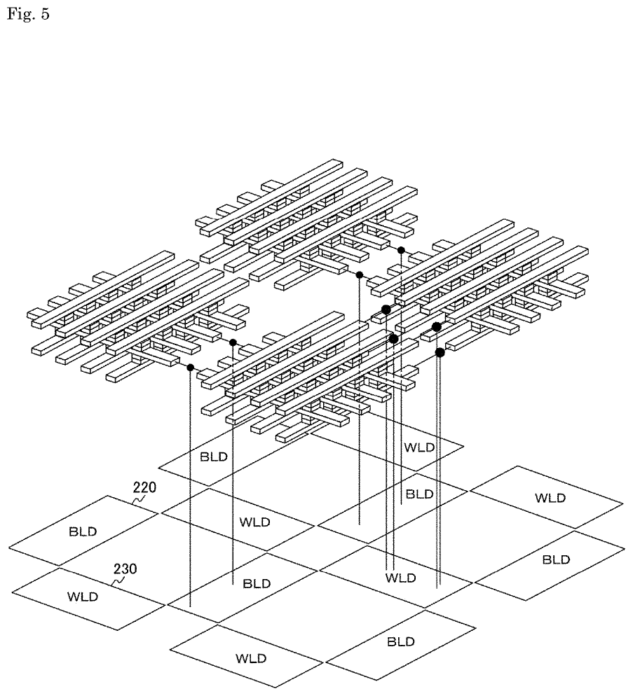

FIG. 5 is a diagram illustrating an example of a configuration of a tile in the memory bank 310 in an embodiment of the present technology.

A structure in which a total of four sub-tiles described above are disposed on a plane with two in the vertical direction and two in the horizontal direction is referred to as a tile. Here, adjoining sub-tiles share the bit line decoder 220 and the word line decoder 230.

### [Notation]

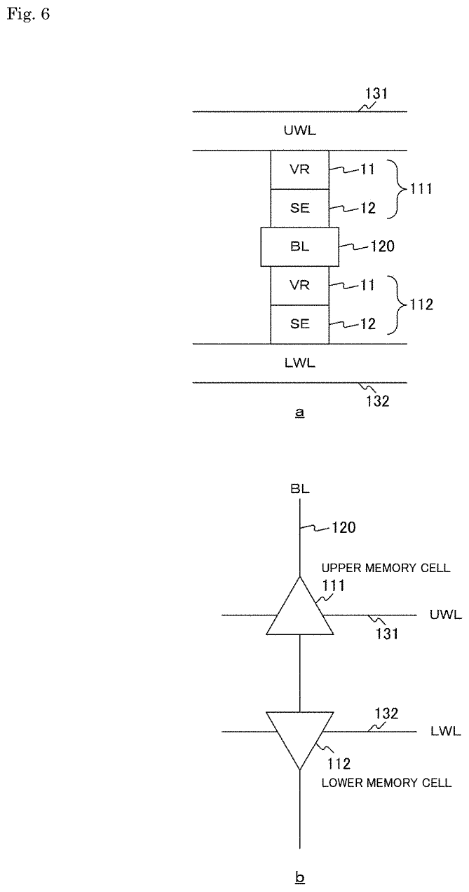

FIG. 6 is a diagram illustrating an example of notation of the upper memory cell 111 and the lower memory cell 112 in an embodiment of the present technology.

In the memory array in this embodiment, the upper memory cell 111 is connected to upper word line 131 and the bit line 120 and the lower memory cell 112 is connected to the bit line 120 and the lower word line 132 as illustrated in a cross-sectional view indicated by a in the figure. In this cross-sectional view, the bit line 120 extends in the depth direction from the front side.

Accordingly, a relation between the upper memory cell 111 and the lower memory cell 112, and the bit line 120, the upper word line 131 and the lower word line 132 is denoted as indicated by b in the figure.

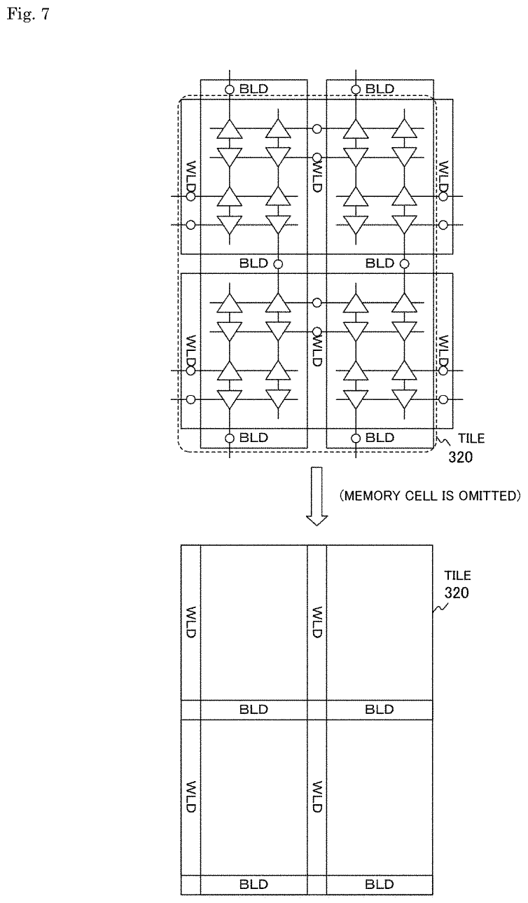

FIG. 7 is a diagram illustrating an example of notation of the tile 320 in an embodiment of the present technology.

When the aforementioned notation is used, the tile 320 can be represented on the plane as illustrated in the figure. However, the bit lines 120, the upper word lines B1, the lower word lines 132, the bit line decoder 220, and the word line decoder 230 at the edge of the tile 320 are shared by neighboring tiles, and thus a boundary needs to be defined. Accordingly, here, it is assumed that the word line decoder 230 on the left side and the bit line decoder 220 on the lower side belong to the tile 320 and the word line decoder 230 on the right side and the bit line decoder 220 on the upper side belong to a neighboring tile 320.

### [Voltage]

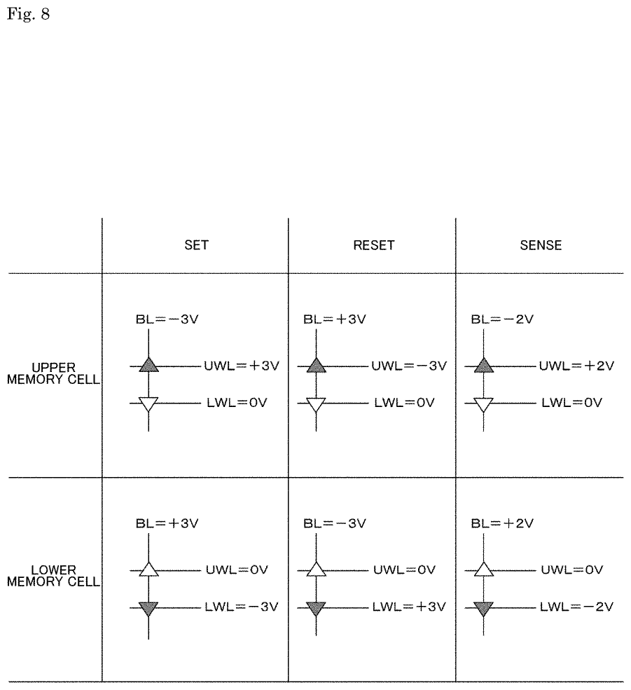

FIG. 8 is a diagram illustrating an example of voltages applied to the upper memory cell 111 and the lower memory cell 112 in an embodiment of the present technology.

As described above, the upper word line 131 is connected to the variable resistor 11 in the upper memory cell 111 and the bit line 120 is connected to the variable resistor 11 in the lower memory cell 112. Accordingly, voltages with different polarities are applied to the bit line 120 and the upper and lower word lines B1 and 132 in the upper memory cell 111 and the lower memory cell 112.

That is, −3 V, for example, is applied to the bit line 120 and +3 V, for example, is applied to the upper word line 131 in the upper memory cell 111 in the set operation. On the other hand, the polarity is reversed in the lower memory cell 112, and thus +3 V, for example, is applied to the bit line 120 and −3 V, for example, is applied to the lower word line 132.

In addition, in the reset operation, the polarity is reverse to that in the aforementioned set operation, and thus +3 V, for example, is applied to the bit line 120 and −3 V, for example, is applied to the upper word line 131 in the upper memory cell 111. On the other hand, the polarity is reversed in the lower memory cell 112, and thus −3 V, for example, is applied to the bit line 120 and +3 V, for example, is applied to the lower word line 132.

Further, in the sense operation, a potential difference decreases with the same polarity as that in the aforementioned set operation. That is, −2 V, for example, is applied to the bit line 120 and +2 V, for example, is applied to the upper word line 131 in the upper memory cell 111. On the other hand, the polarity is reversed in the lower memory cell 112, and thus +2 V, for example, is applied to the bit line 120 and −2 V, for example, is applied to the lower word line 132.

Meanwhile, potential values represented here are exemplary and can be appropriately set according to characteristics of the memory cell 10.

### [Bank]

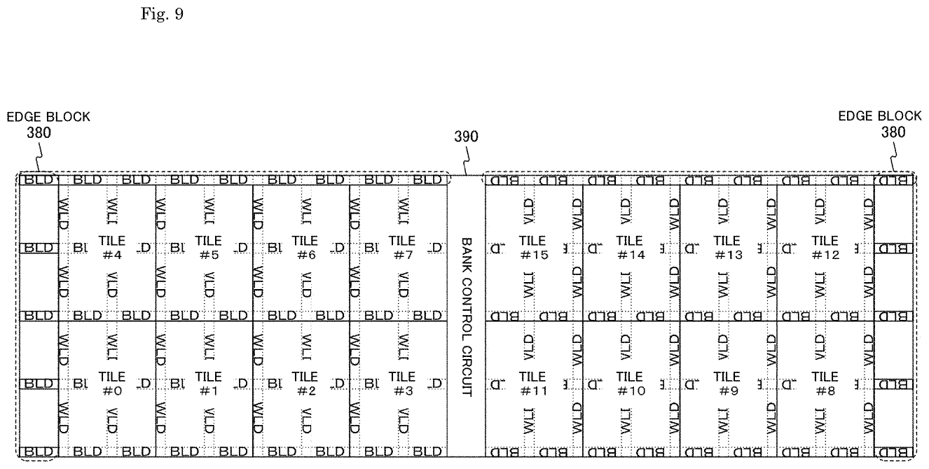

FIG. 9 is a diagram illustrating an example of a circuit layout of the memory bank 310 in an embodiment of the present technology. In this example, a total of 16 tiles are disposed on the left and right of the bank control circuit 390 with eight tiles in two rows and four columns constituting the memory bank 310.

As described above, the bit lines 120, the upper word lines B1, the lower word lines 132, and parts of the word line decoder 230 and the bit line decoder 220 at the edge of the tile belong to a neighboring tile. Here, the edge of the memory bank 310 requires the bit line decoder 220 that does not belong to any tile. A structure including the bit line decoder 220 that does not belong to any tile is referred to as an edge block 380.

### [Memory Die]

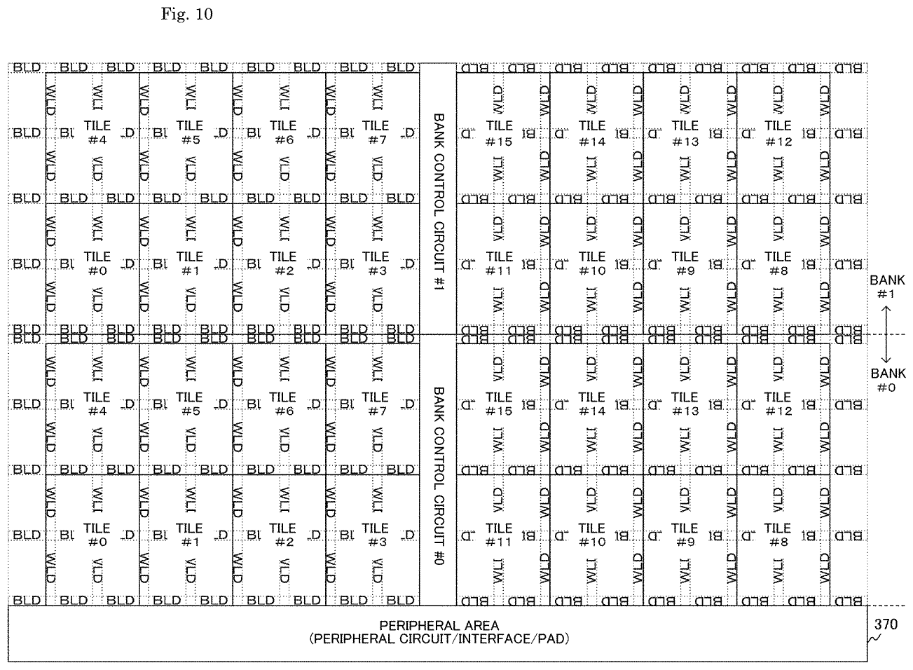

FIG. 10 is a diagram illustrating an example of a circuit layout of a memory die of the storage device 300 in an embodiment of the present technology.

In this example, two memory banks #0 and #1 are included. That is, two memory banks 310 in the above-described circuit layout example are independently arranged.

In addition, in this example, a peripheral area 370 is provided. The peripheral area 370 includes the aforementioned interface 371. Further, the peripheral area 370 includes other peripheral circuits, pads, and the like.

### [Voltage Application Patterns]

Hereinafter, patterns of voltages applied to each tile at the time of the set operation or the sense operation and at the time of the reset operation will be separately described. In the following figures, a white circle indicates a zero potential, “+” indicates a positive potential, and “−” indicates a negative potential. As described above, the positive potential is +3 V and the negative potential is −3 V in the set operation and the reset operation. In addition, the positive potential is +2 V and the negative potential is −2 V in the sense operation.

Further, the 16 upper memory cells 111 in the tile are distinguished by memory cells U0 to U15 and the 16 lower memory cells 112 are distinguished by memory cells L0 to L15. In addition, the upper word lines B1 and the lower word lines 132 in and over the tile are distinguished by word lines w0 to w11 and the bit lines 120 are distinguished by b0 to b5.

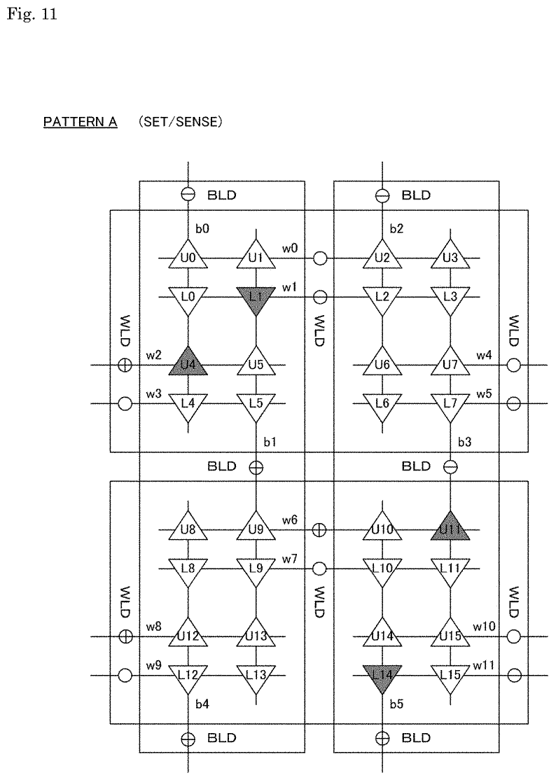

FIG. 11 is a diagram illustrating a first pattern example (pattern A) of applied voltages at the time of the set operation or the sense operation in an embodiment of the present technology.

In pattern A, the negative potential is applied to bit lines b0, b2, and b3 and the positive potential is applied to bit lines b1, b4, and b5. In addition, a zero potential is applied to word lines w0, w3, w4, w7, w9, and w10, the negative potential is applied to word lines w1, w5, and w11, and the positive potential is applied to word lines w2, w6, and w8.

Accordingly, four memory cells L1, U4, U11, and L14 are simultaneously selected and the set operation or the sense operation is performed. Here, current paths are independent and do not obstruct access to each other.

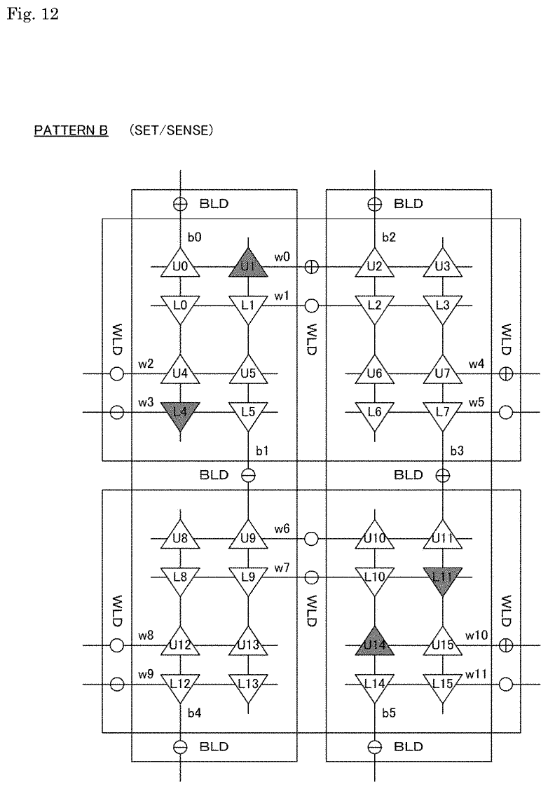

FIG. 12 is a diagram illustrating a second pattern example (pattern B) of the applied voltages at the time of a set operation or a sense operation in an embodiment of the present technology.

In pattern B, the negative potential is applied to bit lines B1, b4, and b5 and the positive potential is applied to bit lines b0, b2, and b3. In addition, a zero potential is applied to word lines w1, w2, w5, w6, w8, and w11, the negative potential is applied to word lines w3, w7, and w9, and the positive potential is applied to word lines w0, w4, and w10.

Accordingly, four memory cells U1, L4, L11, and U14 are simultaneously selected and the set operation or the sense operation is performed. Here, current paths are independent and do not obstruct access each other.

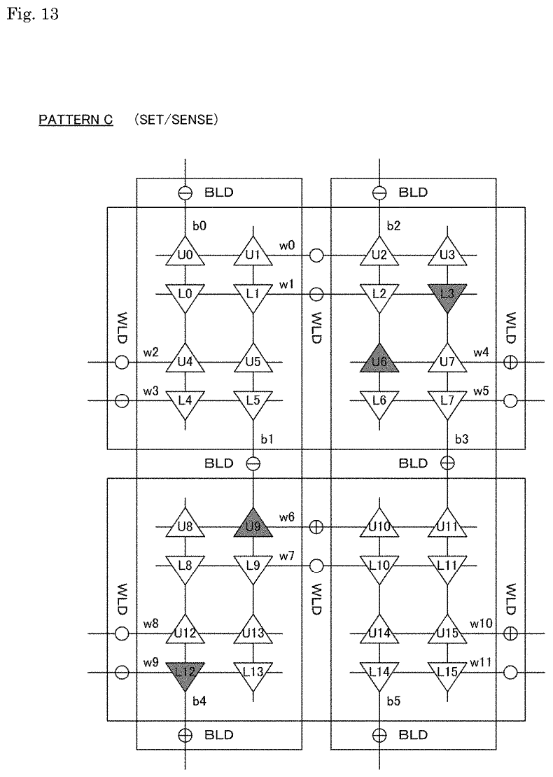

FIG. 13 is a diagram illustrating a third pattern example (pattern C) of the applied voltages at the time of the set operation or the sense operation in an embodiment of the present technology.

In pattern C, the negative potential is applied to bit lines b0, 131, and b2 and the positive potential is applied to bit lines b3, b4, and b5. In addition, a zero potential is applied to word lines w0, w2, w5, w7, w8, and w11, the negative potential is applied to word lines w1, w3, and w9, and the positive potential is applied to word lines w4, w6, and w10.

Accordingly, four memory cells L3, U6, U9, and L12 are simultaneously selected and the set operation or the sense operation is performed. Here, current paths are independent and do not obstruct access each other.

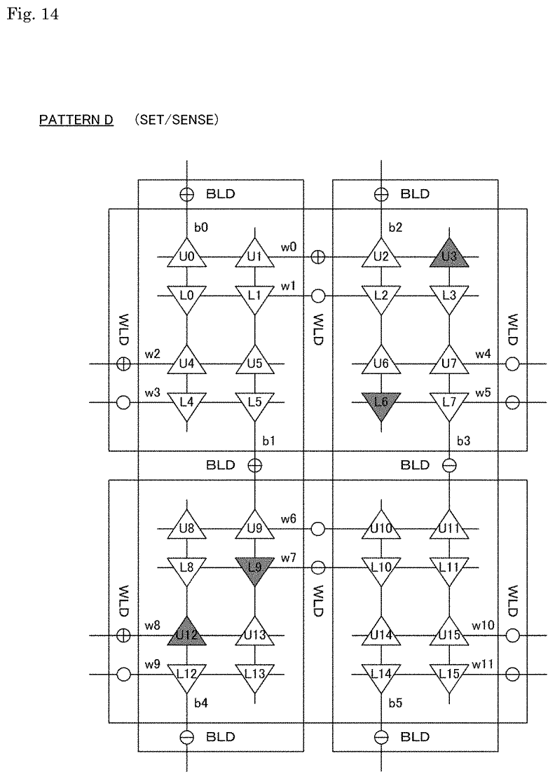

FIG. 14 is a diagram illustrating a fourth pattern example (pattern D) of the applied voltages at the time of the set operation or the sense operation in an embodiment of the present technology.

In pattern D, the negative potential is applied to bit lines b3, b4, and b5 and the positive potential is applied to bit lines b0, 131, and b2. In addition, a zero potential is applied to word lines w1, w3, w4, w6, w9, and w10, the negative potential is applied to word lines w5, w7, and w11, and the positive potential is applied to word lines w0, w2, and w8.

Accordingly, four memory cells U3, L6, L9, and U12 are simultaneously selected and the set operation or the sense operation is performed. Here, current paths are independent and do not obstruct access each other.

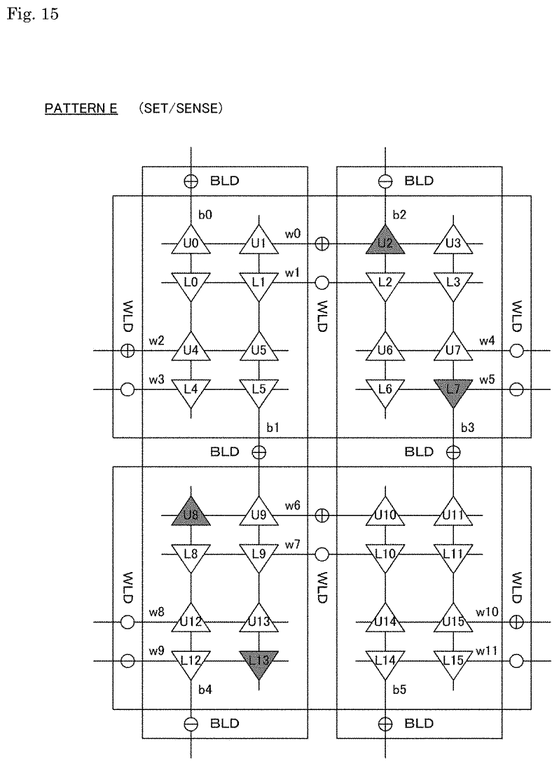

FIG. 15 is a diagram illustrating a fifth pattern example (pattern E) of the applied voltages at the time of the set operation or the sense operation in an embodiment of the present technology.

In pattern E, the negative potential is applied to bit lines b2 and b4 and the positive potential is applied to bit lines b0, 131, b3, and b5. In addition, a zero potential is applied to word lines w1, w3, w4, w7, w8, and w11, the negative potential is applied to word lines w5 and w9, and the positive potential is applied to word lines w0, w2, w6, and w10.

Accordingly, four memory cells U2, L7, U8, and L13 are simultaneously selected and the set operation or the sense operation is performed. Here, current paths are independent and do not obstruct access each other.

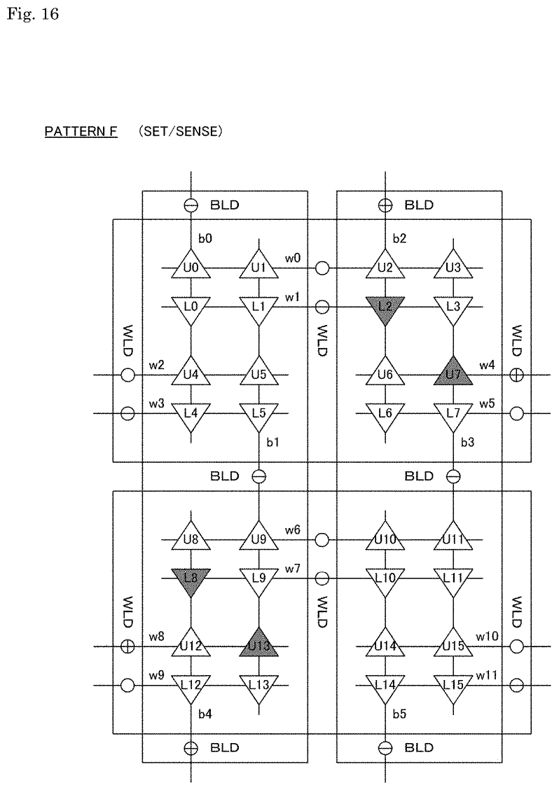

FIG. 16 is a diagram illustrating a sixth pattern example (pattern F) of the applied voltages at the time of the set operation or the sense operation in an embodiment of the present technology.

In pattern F, the negative potential is applied to bit lines b0, 131, b3, and b5 and the positive potential is applied to bit lines b2 and b4. In addition, a zero potential is applied to word lines w0, w2, w5, w6, w9, and w10, the negative potential is applied to word lines w1, w3, w7, and w11, and the positive potential is applied to word lines w4 and w8.

Accordingly, four memory cells L2, U7, L8, and U13 are simultaneously selected and the set operation or the sense operation is performed. Here, current paths are independent and do not obstruct access each other.

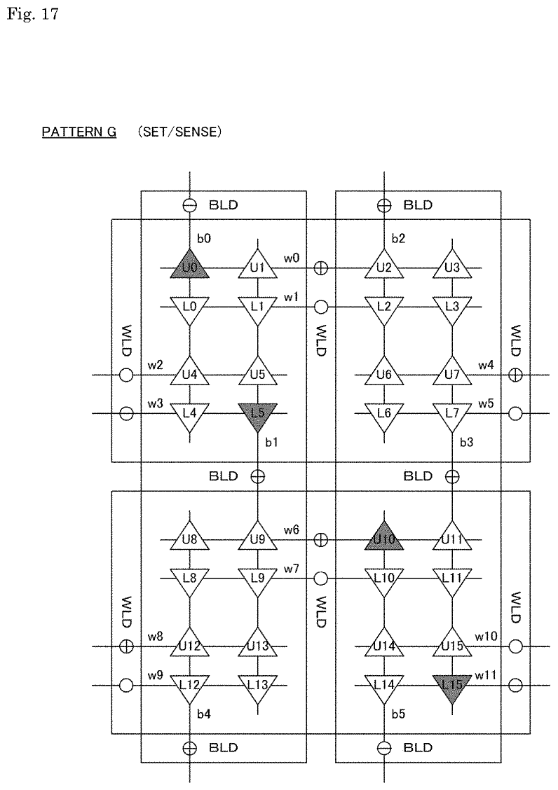

FIG. 17 is a diagram illustrating a seventh pattern example (pattern G) of the applied voltages at the time of the set operation or the sense operation in an embodiment of the present technology.

In pattern G, the negative potential is applied to bit lines b0 and b5 and the positive potential is applied to bit lines B1, b2, b3, and b4. In addition, a zero potential is applied to word lines w1, w2, w5, w7, w9, and w10, the negative potential is applied to word lines w3 and w11, and the positive potential is applied to word lines w0, w4, w6, and w8.

Accordingly, four memory cells U0, L5, U10, and L15 are simultaneously selected and the set operation or the sense operation is performed. Here, current paths are independent and do not obstruct access each other.

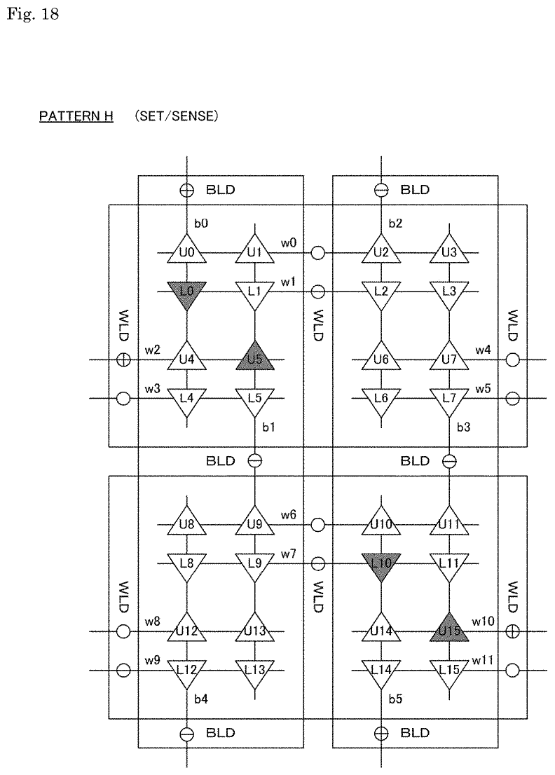

FIG. 18 is a diagram illustrating an eighth pattern example (pattern H) of the applied voltages at the time of the set operation or the sense operation in an embodiment of the present technology.

In pattern H, the negative potential is applied to bit lines B1, b2, b3, and b4 and the positive potential is applied to bit lines b0 and b5. In addition, a zero potential is applied to word lines w0, w3, w4, w6, w8, and w11, the negative potential is applied to word lines w1, w5, w7, and w9, and the positive potential is applied to word lines w2 and w10.

Accordingly, four memory cells L0, U5, L10, and U15 are simultaneously selected and the set operation or the sense operation is performed. Here, current paths are independent and do not obstruct access each other.

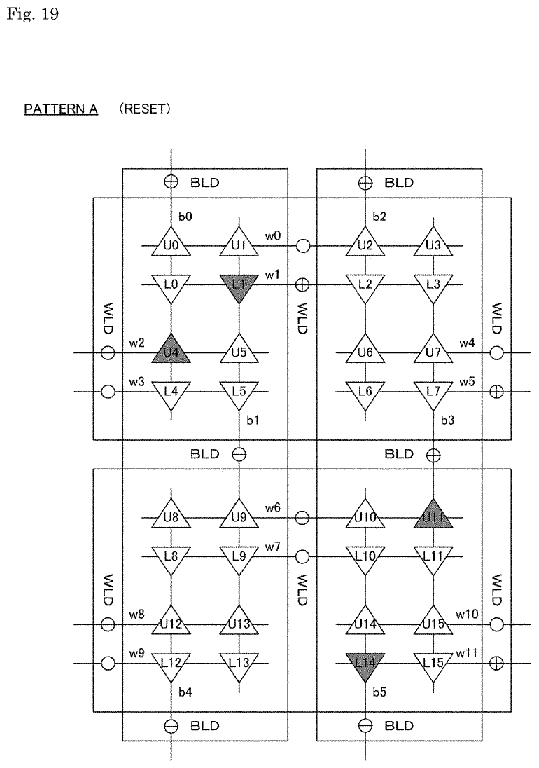

FIG. 19 is a diagram illustrating a first pattern example (pattern A) of applied voltages at the time of the reset operation in an embodiment of the present technology.

In pattern A, the positive potential is applied to bit lines b0, b2, and b3 and the negative potential is applied to bit lines B1, b4, and b5. In addition, a zero potential is applied to word lines w0, w3, w4, w7, w9, and w10, the positive potential is applied to word lines w1, w5, and w11, and the negative potential is applied to word lines w2, w6, and w8.

Accordingly, four memory cells L1, U4, U11, and L14 are simultaneously selected and the reset operation is performed. Here, current paths are independent and do not obstruct access each other.

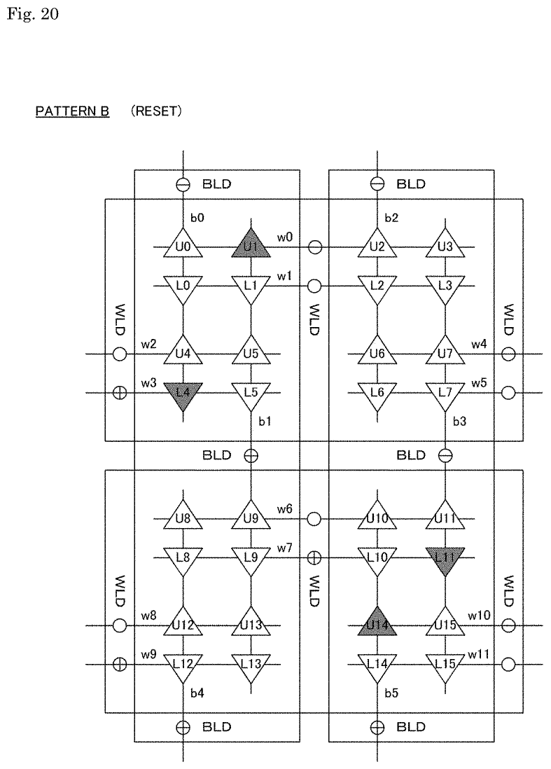

FIG. 20 is a diagram illustrating a second pattern example (pattern B) of the applied voltages at the time of the reset operation in an embodiment of the present technology.

In pattern B, the positive potential is applied to bit lines B1, b4, and b5 and the negative potential is applied to bit lines b0, b2, and b3. In addition, a zero potential is applied to word lines w1, w2, w5, w6, w8, and w11, the positive potential is applied to word lines w3, w7, and w9, and the negative potential is applied to word lines w0, w4, and w10.

Accordingly, four memory cells U1, L4, L11, and U14 are simultaneously selected and the reset operation is performed. Here, current paths are independent and do not obstruct access each other.

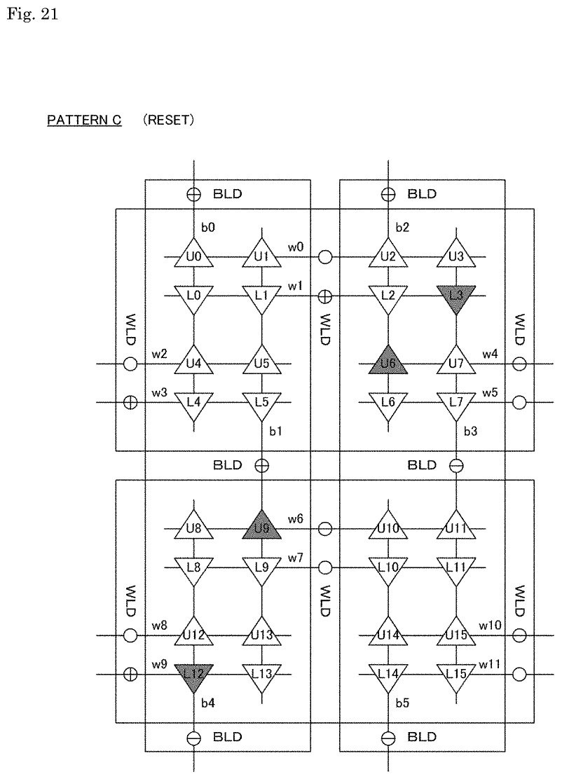

FIG. 21 is a diagram illustrating a third pattern example (pattern C) of the applied voltages at the time of the reset operation in an embodiment of the present technology.

In pattern C, the positive potential is applied to bit lines b0, 131, and b2 and the negative potential is applied to bit lines b3, b4, and b5. In addition, a zero potential is applied to word lines w0, w2, w5, w7, w8, and w11, the positive potential is applied to word lines w1, w3, and w9, and the negative potential is applied to word lines w4, w6, and w10.

Accordingly, four memory cells L3, U6, U9, and L12 are simultaneously selected and the reset operation is performed. Here, current paths are independent and do not obstruct access each other.

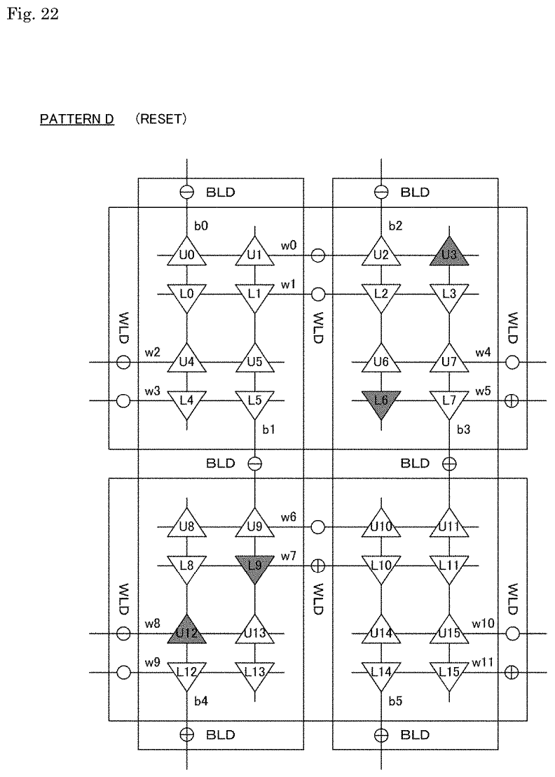

FIG. 22 is a diagram illustrating a fourth pattern example (pattern D) of the applied voltages at the time of the reset operation in an embodiment of the present technology.

In pattern D, the positive potential is applied to bit lines b3, b4, and b5 and the negative potential is applied to bit lines b0, 131, and b2. In addition, a zero potential is applied to word lines w1, w3, w4, w6, w9, and w10, the positive potential is applied to word lines w5, w7, and w11, and the negative potential is applied to word lines w0, w2, and w8.

Accordingly, four memory cells U3, L6, L9, and U12 are simultaneously selected and the reset operation is performed. Here, current paths are independent and do not obstruct access each other.

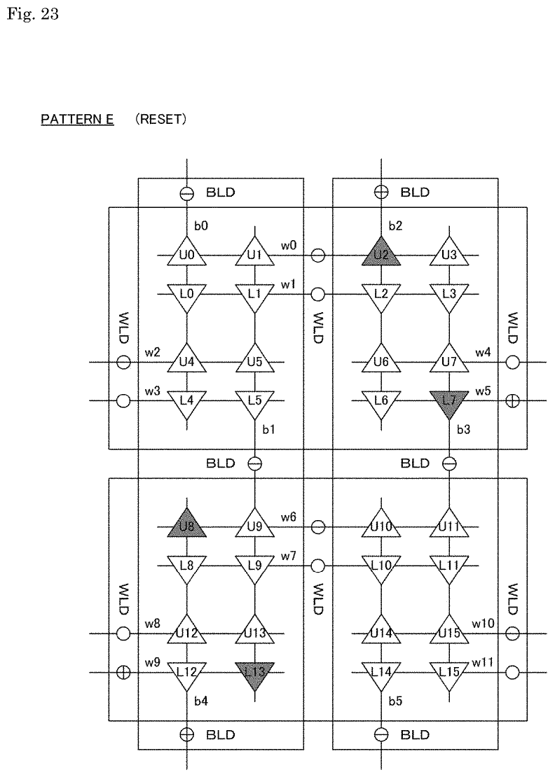

FIG. 23 is a diagram illustrating a fifth pattern example (pattern E) of the applied voltages at the time of the reset operation in an embodiment of the present technology.

In pattern E, the positive potential is applied to bit lines b2 and b4 and the negative potential is applied to bit lines b0, 131, b3, and b5. In addition, a zero potential is applied to word lines w1, w3, w4, w7, w8, and w11, the positive potential is applied to word lines w5 and w9, and the negative potential is applied to word lines w0, w2, w6, and w10.

Accordingly, four memory cells U2, L7, U8, and L13 are simultaneously selected and the reset operation is performed. Here, current paths are independent and do not obstruct access each other.

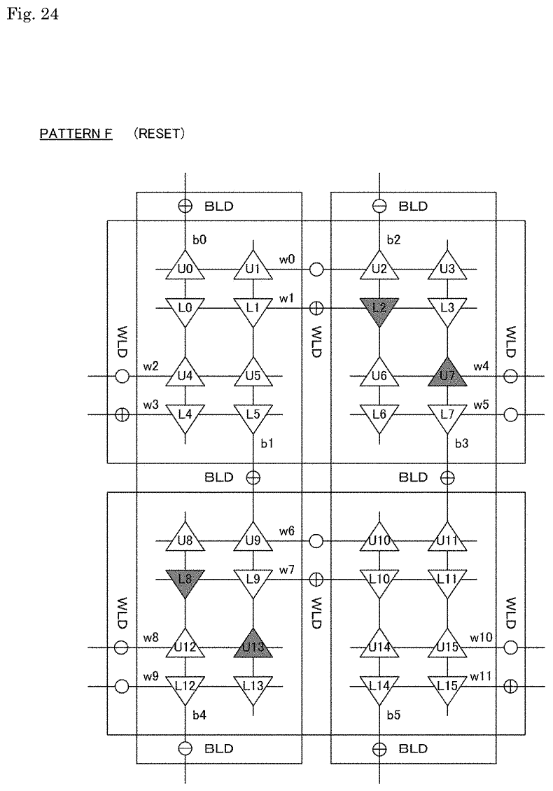

FIG. 24 is a diagram illustrating a sixth pattern example (pattern F) of the applied voltages at the time of the reset operation in an embodiment of the present technology.

In pattern F, the positive potential is applied to bit lines b0, 131, b3, and b5 and the negative potential is applied to bit lines b2 and b4. In addition, a zero potential is applied to word lines w0, w2, w5, w6, w9, and w10, the positive potential is applied to word lines w1, w3, w7, and w11, and the negative potential is applied to word lines w4 and w8.

Accordingly, four memory cells L2, U7, L8, and U13 are simultaneously selected and the reset operation is performed. Here, current paths are independent and do not obstruct access each other.

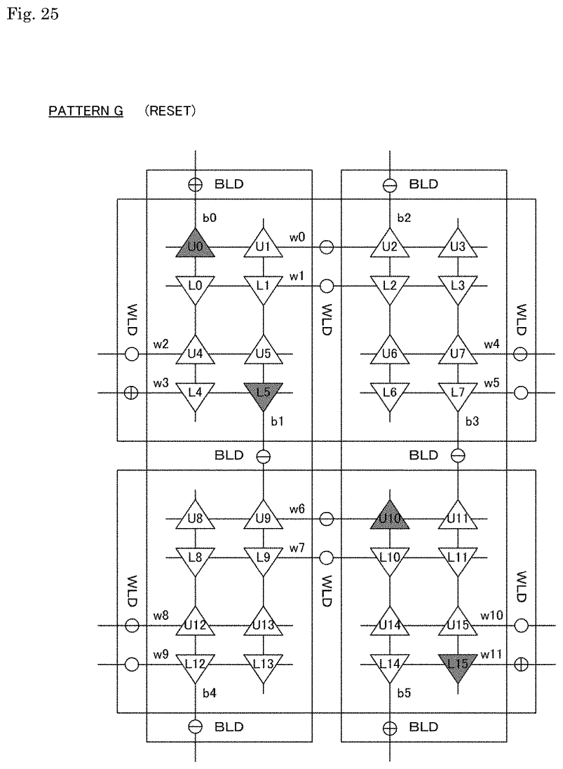

FIG. 25 is a diagram illustrating a seventh pattern example (pattern G) of the applied voltages at the time of the reset operation in an embodiment of the present technology.

In pattern G, the positive potential is applied to bit lines b0 and b5 and the negative potential is applied to bit lines B1, b2, b3, and b4. In addition, a zero potential is applied to word lines w1, w2, w5, w7, w9, and w10, the positive potential is applied to word lines w3 and w11, and the negative potential is applied to word lines w0, w4, w6, and w8.

Accordingly, four memory cells U0, L5, U10, and L15 are simultaneously selected and the reset operation is performed. Here, current paths are independent and do not obstruct access each other.

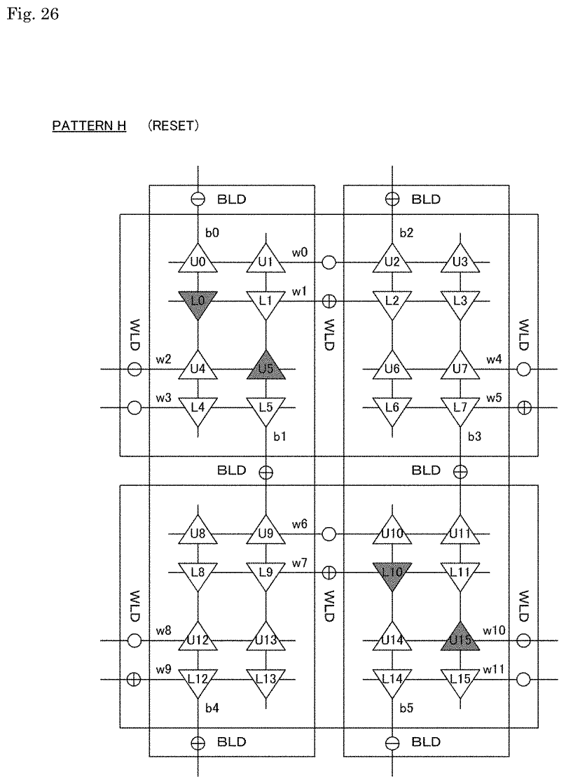

FIG. 26 is a diagram illustrating an eighth pattern example (pattern H) of the applied voltages at the time of the reset operation in an embodiment of the present technology.

In pattern H, the positive potential is applied to bit lines B1, b2, b3, and b4 and the negative potential is applied to bit lines b0 and b5. In addition, a zero potential is applied to word lines w0, w3, w4, w6, w8, and w11, the positive potential is applied to word lines w1, w5, w7, and w9, and the negative potential is applied to word lines w2 and w10.

Accordingly, four memory cells L0, U5, L10, and U15 are simultaneously selected and the reset operation is performed. Here, current paths are independent and do not obstruct access each other.

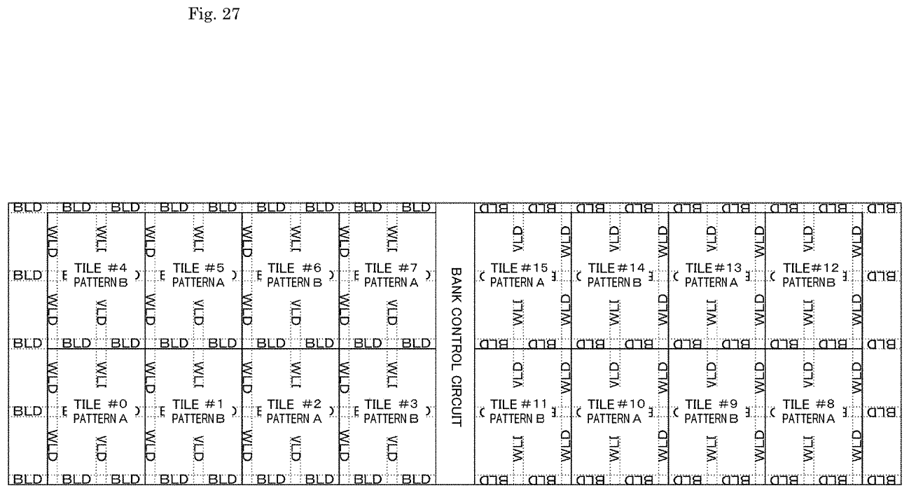

FIG. 27 is a diagram illustrating an example of arrangement of patterns of applied voltages in an embodiment of the present technology.

The patterns at the time of the aforementioned set operation or sense operation and at the time of the reset operation are used by being combined such that they have different polarities in adjoining tiles. For example, as illustrated in the figure, pattern A is used in tiles #0, #2, #5, #7, #8, #10, #13, and #15 and pattern B is used in other tiles #1, #3, #4, #6, #9, #11, #12, and #14. Accordingly, it is possible to simultaneously access four memory cells in each tile while matching the bit line decoder 220 and the word line decoder 230 of a neighboring tile.

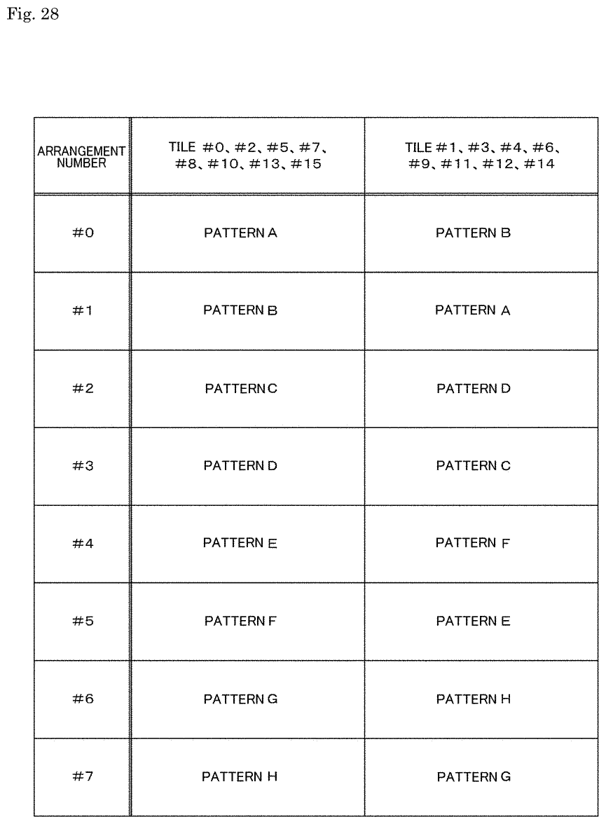

FIG. 28 is a diagram illustrating an example of combinations of arrangements of patterns of applied voltages in an embodiment of the present technology.

Arrangement number #0 corresponds to the aforementioned example in which pattern A is used in tiles #0, #2, #5, #7, #8, #10, #13, and #15 and pattern B is used in other tiles #1, #3, #4, #6, #9, #11, #12, and #14. In addition, arrangement number #1 corresponds to an example in which pattern A and pattern B of arrangement number #0 are changed.

Likewise, arrangement numbers #2 and #3 correspond to arrangements in which pattern C and pattern D are changed, arrangement numbers #4 and #5 correspond to arrangements in which pattern E and pattern F are changed, and arrangement numbers #6 and #7 correspond to arrangements in which pattern G and pattern H are changed.

According to a total of eight pattern arranges in this manner, it is possible to simultaneously access four memory cells in each tile for all memory cells without duplication.

In these patterns, the bit line decoder 220 supplies a first voltage having either a positive or a negative polarity to each bit line. That is, +3 V or −3 V is the first voltage in the set operation and the reset operation and +2 V or −2 V is the first voltage in the sense operation.

On the other hand, the word line decoder 230 supplies a second voltage having a polarity reverse to that of the first voltage to one of word lines intersecting bit lines to which the first voltage is supplied. That is, when +3 V, for example, is supplied as the first voltage, −3 V is the second voltage. In addition, the word line decoder 230 supplies a voltage having the same polarity as that of the first voltage or zero voltage to the remaining word lines (to which the second voltage is not supplied). That is, when +3 V, for example, is supplied as the first voltage, +3 V or 0 V is supplied to the remaining word lines. Accordingly, only a single memory cell is selected in the same bit line and word line and thus an independent current path can be secured.

### [Address Signal]

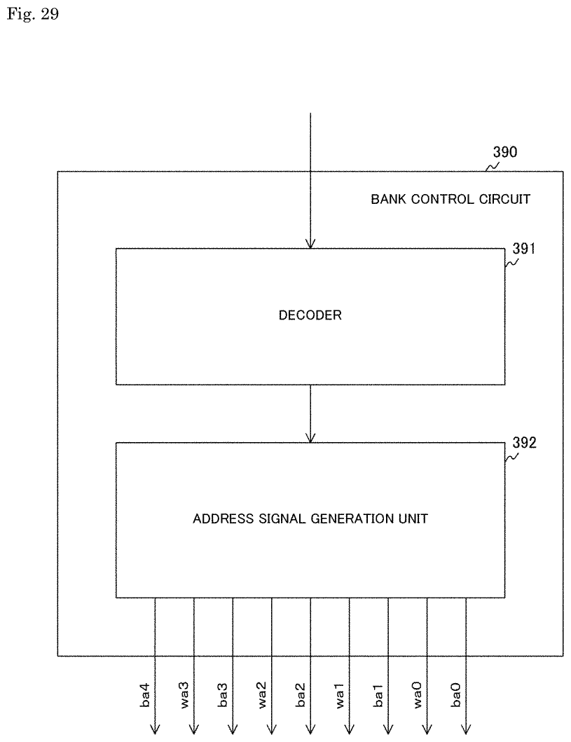

FIG. 29 is a diagram illustrating an example of a configuration of the bank control circuit 390 in an embodiment of the present technology.

The bank control circuit 390 includes a decoder 391 and an address signal generation unit 392. The decoder 391 is a circuit that decodes an address of a command issued by the host computer 500.

The address signal generation unit 392 generates an address signal according to a decoding result of the decoder 391. In this example, five bit line address signals ba0 to ba4 and four word line address signals wa0 to wa3 are supplied through address lines.

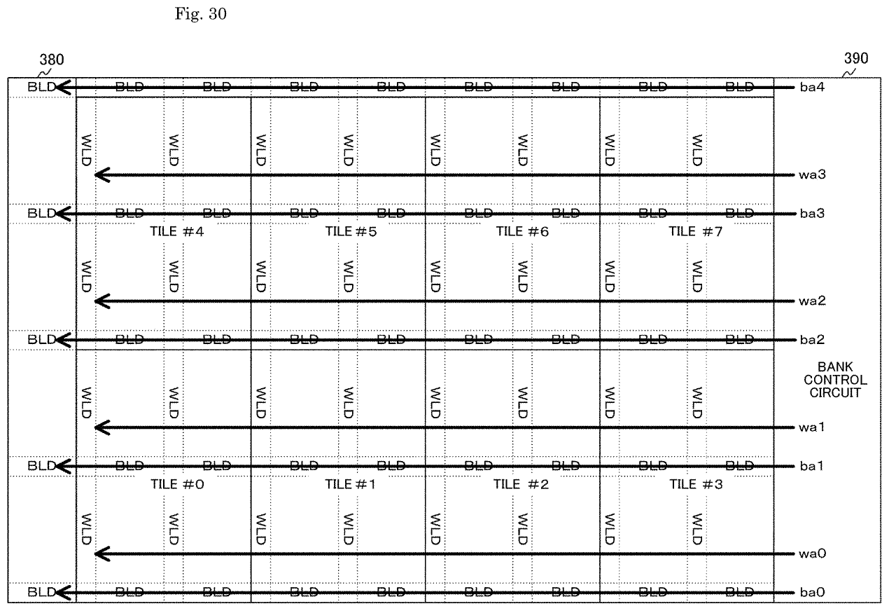

FIG. 30 is a diagram illustrating an example of arrangement of address lines for supplying address signals from the bank control circuit 390 in an embodiment of the present technology.

As described above, the bank control circuit 390 is disposed at the center of the memory bank 310. The bank control circuit 390 supplies the bit line address signals ba0 to ba4 and the word line address signals wa0 to wa3 to the bit line decoder 220 and the word line decoder 230 disposed on the left and right thereof.

The bit line address signals and the word line address signals are shared by left and right tiles. In addition, the bit line address signals are also supplied to the edge block 380.

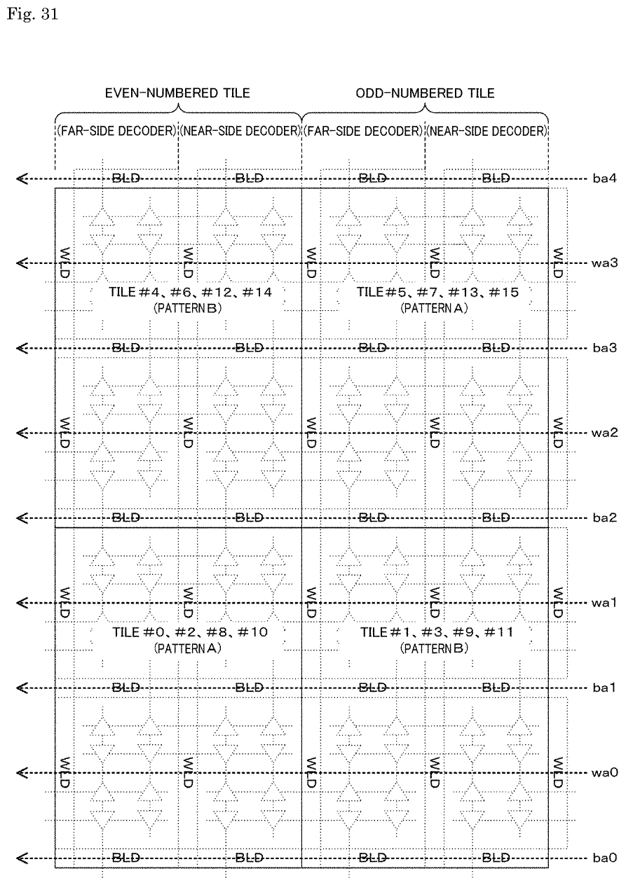

FIG. 31 is a diagram illustrating an example of names of address signals supplied from the bank control circuit 390 in an embodiment of the present technology.

In this example, on the assumption that the bank control circuit 390 is disposed on the right side, an even-numbered tile is represented on the left side and an odd-numbered tile is represented on the right side.

In each tile, the same bit line signal and word line signal are supplied to two bit line decoders 220 and word line decoders 230. At that time, a side closer to the bank control circuit 390 is referred to as a near side and a side far from the bank control circuit 390 is referred to as a far side.

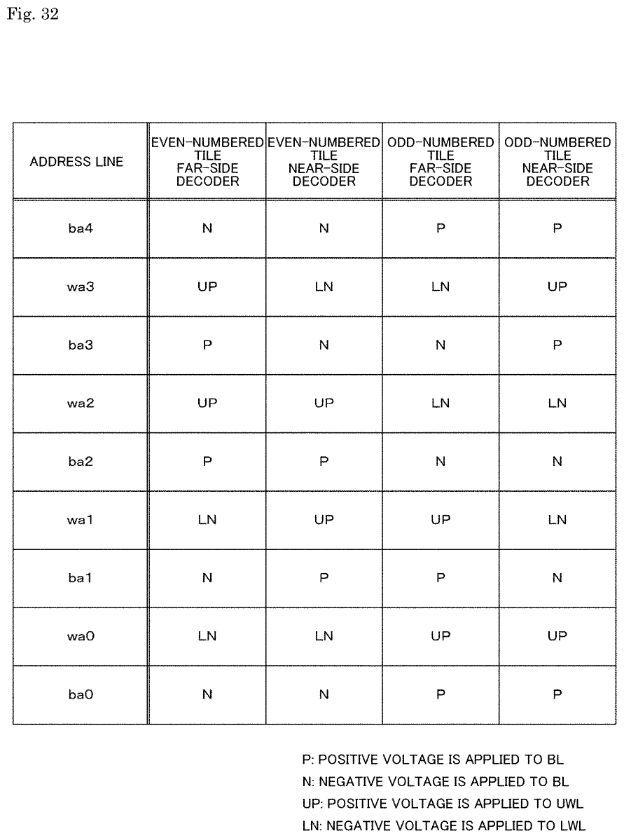

FIG. 32 is a diagram illustrating an example of details of the address signals supplied from the bank control circuit 390 in an embodiment of the present technology.

The bit line address signals ba0 to ba4 represent polarities of a voltage applied to bit lines. For example, if a bit line address signal is “P,” it represents that a positive voltage is applied to bit lines. On the other hand, if a bit line address signal is “N,” it represents that a negative voltage is applied to the bit lines.

The word line address signals wa0 to wa3 represent information indicating which one of the upper word line 131 and the lower word line 132 is a target and information on polarities of a voltage applied to word lines. For example, if a word line address signal is “UP,” it represents that a positive voltage is applied to the upper word lines B1. On the other hand, if a word line address signal is “LN,” it represents that a negative voltage is applied to the lower word lines 132.

### [Sense Amplifier]

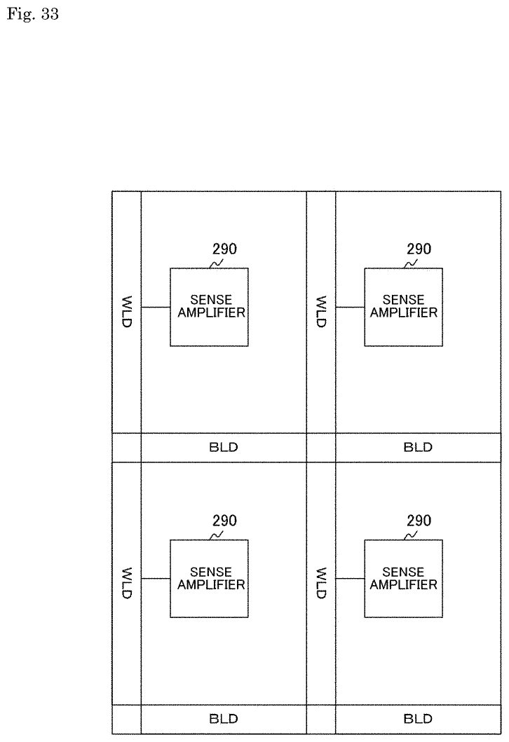

FIG. 33 is a diagram illustrating an example of arrangement of sense amplifiers 290 in an embodiment of the present technology.

Reading in the cross point memory can be performed through any of a word line and a bit line. However, it is desirable to perform reading on a side having a smaller parasitic capacitance. That is, in terms of a speed, a detection time of a current or a voltage of a memory cell is shorter when capacitance is smaller. In addition, in terms of the lifespan of memory cells, charges stored in a parasitic capacitance flow to the memory cells whenever reading is performed and thus may cause deterioration.

In this embodiment, the word lines have a smaller parasitic capacitance because the word lines are connected to only first-level memory cells whereas the bit lines are shared by the second-level memory cells. Accordingly, a sense amplifier 290 is connected to the word lines in this embodiment.

To simultaneously access four bits in each tile, four sense amplifiers 290 are necessary per tile. Even in each of the above-described patterns, it is ascertained that four word lines in a tile correspond to a single selected memory cell.

Further, it is desirable that a distance between the sense amplifier 290 and the word line be shorter because the parasitic capacitance decreases. Accordingly, it is desirable to dispose the sense amplifier 290 near the word line decoder 230 as in the figure.

Further, it is desirable to provide different sense amplifiers 290 in the upper level and the lower level of the two-level cross point memory in consideration of restriction on a withstand voltage of a gate voltage of a transistor. Accordingly, the number of sense amplifiers 290 in such a case is set to eight per tile.

In this manner, according to embodiments of the present technology, it is possible to simultaneously select and access four memory cells in each tile by securing an independent current path according to a voltage supplied from the bit line decoder 220 and the word line decoder 230. Accordingly, it is possible to improve parallelism of access in the cross point memory and to reduce power consumption.

### <2. Modified Examples>

In the above-described embodiment, an example assuming a two-level cross point memory sharing the bit lines 120 has been described. The present technology can also be applied to a three-level cross point memory in which upper bit lines are superimposed on the upper word lines B1 and third-level memory layers are formed between the upper word lines B1 and the upper bit lines as a modified example. Furthermore, the present technology can also be applied to a four-level cross point memory in which third word lines are superimposed on the top. However, the number of bits that can be simultaneously selected in such cases is 4 bits per tile as in the two-level cross point memory.

In addition, as another modified example, the present technology can also be applied to a four-level cross point memory in which two two-level cross point memories are stacked without sharing word lines. In this case, it is posspective correspondence relation with the specific factors of the invention in the claims. Similarly, the specific factors of the invention in the claims have the respective correspondence relation with the factors with the same names in the embodiment of the present technology. Here, the present technology is not limited to the embodiment and various modifications of the embodiment can be made within the scope of the present technology without departing from the gist of the present technology.

In addition, the structure and characteristics of the memory cell 10 described in the above-described embodiment are merely examples and are not limited as components of the present technology. For example, the following variation may be conceived, but the present technology can be equally applied to any modification.

(a) In the above-described embodiment, voltages are applied in the same direction in the set operation and the sense operation and voltages are applied in opposite directions in the set operation and the reset operation. In contrast, a memory cell in which voltages may be applied in opposite direction in the set operation and the sense operation and voltages may be applied in the same direction in the reset operation and the sense operation may be realized. In addition, a memory cell in which voltages are applied in the same direction in all the set, reset, and sense operations may be realized. The latter case is generally referred to as a unipolar type.

(b) Although the memory cell 10 has a serial structure of the variable resistor 11 and the selector 12 in the above-described embodiment, the memory cell 10 may be composed of a single element having both resistance variable characteristics and diode characteristics.

(c) The present technology can be applied to the memory cell 10 if it has a structure including a variable resistance element in a broad sense irrespective of the operation principle and material composition thereof. The variable resistance element in a broad sense includes, for example, a phase change memory (PCM), a magnetoresistive random access memory (MRAM), a ferroelectric random access memory (FeRAM), a spin transfer torque random access memory (STT-RAM), and a carbon nanotube memory (CBRAM).

The advantageous effects in the embodiments described in the present specification are merely exemplary and are not limited, and other advantageous effects may be obtained.

The present technology can be configured as follows.

(1)

A storage device including a storage unit including a plurality of first lines extending in a first direction, a plurality of second lines extending in a second direction different from the first direction, and a plurality of memory cells each being inserted at a position at which any one of the plurality of first lines intersects any one of the plurality of second lines,

a plurality of first driving units configured to supply a first voltage having either a positive or a negative polarity to the plurality of first lines, and

a plurality of second driving units configured to supply a second voltage having a polarity different from the first voltage to one of the plurality of second lines intersecting the plurality of first lines and to supply either a zero potential or a voltage having the same polarity as the first voltage to the remaining second lines intersecting the plurality of first lines.

(2)

The storage device according to (1) above, wherein

the plurality of first driving units are provided for the plurality of memory cells sharing one of the plurality of first lines, and

the plurality of second driving units are provided for the plurality of memory cells sharing one of the plurality of second lines.

(3)

The storage device according to (1) or (2) above, wherein, when divided into a plurality of unit structures including a predetermined number of the plurality of first driving units and a predetermined number of the plurality of second driving units, voltage supply patterns for the plurality of first and second lines of neighboring unit structures among the plurality of unit structures are different from each other.

(4)

The storage device according to (3) above, wherein the plurality of first and second driving units at a boundary between neighboring unit structures among the plurality of unit structures are shared by the neighboring unit structures.

(5)

The storage device according to any one of (1) to (4) above, wherein each of the plurality of memory cells includes a storage element having either a first resistance state or a second resistance state, and

the storage element is set to either the first resistance state or the second resistance state in response to a direction of current flowing when voltages with different polarities are applied to the first and second lines.

(6)

The storage device according to any one of (1) to (5) above, wherein the plurality of memory cells include first and second storage elements sharing one of the plurality of first lines.

(7)

The storage device according to (6) above, wherein the plurality of second driving units supply a voltage with a zero potential to the second line of one of the first and second storage elements and supply a voltage having either a positive or a negative polarity to the second line of the other.

(8)

The storage device according to any one of (1) to (7) above, further including a plurality of sense amplifiers connected to the plurality of second lines to correspond to the plurality of second driving units.

(9)

The storage device according to any one of (1) to (8) above, further including a control circuit configured to supply a control signal indicating polarities of voltages to be applied to the plurality of first and second lines to the plurality of first and second driving units.

(10)

A storage control device for controlling a storage device including a plurality of first lines extending in a first direction, a plurality of second lines extending in a second direction different from the first direction, and a plurality of memory cells each being inserted at a position at which any of the plurality of first lines intersects any of the plurality of second lines, the storage control device including a plurality of first driving units configured to supply a first voltage having either a positive or a negative polarity to the plurality of first lines, and a plurality of second driving units configured to supply a second voltage having a polarity different from the first voltage to one of the plurality of second lines intersecting the plurality of first lines and to supply either a zero potential or a voltage having the same polarity as the first voltage to the remaining second lines intersecting the plurality of first lines.

### REFERENCE SIGNS LIST

10 Memory cell
11 Variable resistor
12 Selector
18 Upper terminal
19 Lower terminal
111 Upper memory cell
112 Lower memory cell
120 Bit line
131 Upper word line
132 Lower word line
220 Bit line decoder
230 Word line decoder
290 Sense amplifier
300 Storage device
310 Memory bank
320 Tile
370 Peripheral area
371 Interface
380 Edge block
390 Bank control circuit
391 Decoder
392 Address signal generation unit
400 Memory controller
500 Host computer

What is claimed is:

1. A storage device, comprising:
a storage unit including a plurality of first lines extending in a first direction, a plurality of second lines extending in a second direction different from the first direction, and a plurality of memory cells each being inserted at a position at which any one of the plurality of first lines intersects any one of the plurality of second lines;
a plurality of first driving units configured to supply a first voltage having either a positive or a negative polarity to the plurality of first lines, and
a plurality of second driving units configured to supply a second voltage having a polarity different from the first voltage to one of the plurality of second lines intersecting the plurality of first lines and to supply either a zero potential or a voltage having the same polarity as the first voltage to the remaining second lines intersecting the plurality of first lines.

2. The storage device according to claim 1, wherein
the plurality of first driving units are provided for the plurality of memory cells sharing one of the plurality of first lines, and
the plurality of second driving units are provided for the plurality of memory cells sharing one of the plurality of second lines.

3. The storage device according to claim 1, wherein, when divided into a plurality of unit structures including a predetermined number of the plurality of first driving units and a predetermined number of the plurality of second driving units, voltage supply patterns for the plurality of first and second lines of neighboring unit structures among the plurality of unit structures are different from each other.

4. The storage device according to claim 3, wherein the plurality of first and second driving units at a boundary between neighboring unit structures among the plurality of unit structures are shared by the neighboring unit structures.

5. The storage device according to claim 1, wherein each of the plurality of memory cells includes a storage element having either a first resistance state or a second resistance state, and
the storage element is set to either the first resistance state or the second resistance state in response to a direction of current flowing when voltages with different polarities are applied to the first and second lines.

6. The storage device according to claim 1, wherein the plurality of memory cells include first and second storage elements sharing one of the plurality of first lines.

7. The storage device according to claim 6, wherein the plurality of second driving units supply a voltage with a zero potential to the second line of one of the first and second storage elements and supply a voltage having either a positive or a negative polarity to the second line of the other.

8. The storage device according to claim 1, further comprising a plurality of sense amplifiers connected to the plurality of second lines to correspond to the plurality of second driving units.

9. The storage device according to claim 1, further comprising a control circuit configured to supply a control signal indicating polarities of voltages to be applied to the plurality of first and second lines to the plurality of first and second driving units.

10. A storage control device for controlling a storage device including a plurality of first lines extending in a first direction, a plurality of second lines extending in a second direction different from the first direction, and a plurality of memory cells each being inserted at a position at which any of the plurality of first lines intersects any of the plurality of second lines, the storage control device comprising:
a plurality of first driving units configured to supply a first voltage having either a positive or a negative polarity to the plurality of first lines; and
a plurality of second driving units configured to supply a second voltage having a polarity different from the first voltage to one of the plurality of second lines intersecting the plurality of first lines and to supply either a zero potential or a voltage having the same polarity as the first voltage to the remaining second lines intersecting the plurality of first lines.
